(19) United States
(12) Patent Application Publication
(10) Pub. No.: US 2008/0237711 A1
(43) Pub. Date: Oct. 2, 2008

(54) MANUFACTURING METHOD OF THIN-FILM SEMICONDUCTOR APPARATUS AND THIN-FILM SEMICONDUCTOR APPARATUS

(75) Inventors: Akio Machida, Kanagawa (JP); Toshio Fujino, Kanagawa (JP); Tadahiro Kono, Tokyo (JP)

Correspondence Address: SONNENSCHEIN NATH & ROSENTHAL LLP, P.O. BOX 061080, WACKER DRIVE STATION, SEARS TOWER, CHICAGO, IL, 60606-1080, US

(73) Assignee: SONY CORPORATION, Tokyo (JP)

(21) Appl. No.: 11/857,050

(22) Filed: Sep. 18, 2007

(30) Foreign Application Priority Data
Sep. 19, 2006 (JP) 2006-252008

(51) Int. Cl. H01L 29/786; H01L 21/336

(52) U.S. Cl. 257/347; 438/151; 257/E29.273; 257/E21.411

(57) ABSTRACT

A manufacturing method of a thin-film semiconductor apparatus and a thin-film semiconductor apparatus, in which a semiconductor thin film is spot-irradiated with an energy beam in the presence of n-type or p-type impurity to form a shallow diffusion layer in which the impurity is diffused only in a surface layer of the semiconductor thin film.

### CROSS REFERENCES TO RELATED APPLICATIONS

The present application claims benefit of priority of Japanese patent Application No. 2006-252008 filed in the Japanese Patent Office on Sep. 19, 2006, the entire content of which being incorporated herein by reference.

### BACKGROUND OF THE INVENTION

1. Field of the Invention

The present invention relates to a manufacturing method of a thin-film semiconductor apparatus, and the thin-film semi-conductor apparatus, and particularly, a manufacturing method of a thin-film semiconductor apparatus, and the thin-film semiconductor apparatus capable of preventing leak current from flowing without constructing an LDD structure.

2. Description of Related Art

With development of the advanced information age, demand for a flat panel display device shows no sign of slowing down. More thinned type flat panel display devices with high functions, such as higher definition with larger area, higher contrast, and more excellent moving image characteristics are demanded. For a display device, a technique for manufacturing a thin film transistor (TFT) on a plastic substrate with excellent lightweight properties, flexibility and non destructivity as compared with a related art glass substrate is desired. Moreover, in recent years, a spontaneous light-emitting element represented by organic EL has attracted attention as a current-drive display element, and in terms of reliability at the time of the current driving, a technique for manufacturing a TFT array of a large area using poly-Si TFTs, in each of which poly-Si is used as a channel semiconductor film, is under study. If an active matrix type display apparatus employing the poly-Si TFT as a switching element for a drive circuit can be manufactured on a plastic substrate, an application range to the not known, visionary products will be greatly enlarged.

In these situations, a technique for manufacturing TFTs on a glass substrate using a poly-Si semiconductor film, which can be formed at a low temperature using an excimer laser anneal (ELA) technique, has been further developed, and recently, it has been reported that TFTs were successfully manufactured on a plastic substrate.

However, when the poly-Si TFT is used for a pixel-selecting switching element of a liquid crystal display apparatus or the like, there arises an issue in that display quality is degraded because of large off-current. In other words, in the poly-Si TFT, since current flows via grain boundary of crystal grains composing the semiconductor film, or via a defect inside the grain, large leak current easily occurs. Additionally, since for example, the poly-Si TFT used in the active-matrix-type liquid crystal display apparatus is employed under reverse bias of about 10 V or higher, leak current attributed to impact ions or hot electrons is also a serious issue. This issue is particularly important when the poly-Si TFT is used for a pixel-selecting thin film transistor of a liquid crystal display apparatus.

In order to reduce the leak current in the above-described TFT, relaxation of an electric field at a drain terminal is effective. Therefore, in the general poly-Si TFT, a Lightly Doped Drain (LDD) region with a low impurity concentration (e.g. a concentration lower than an n+ region (high concentration region) by about two to four digits) is provided at the drain terminal at the side of a gate electrode to thereby relax the electric field at the drain terminal.

The manufacturing of the TFT with the above-described LDD region is performed as follows. Agate electrode is first formed through a gate insulating film on a semiconductor thin film, which will be a channel semiconductor film, and next, impurity for forming the LDD region is introduced to the semiconductor thin film, using the gate electrode as a mask. Then, a resist pattern covering the gate electrode and its sides is formed, and using this as a mask, impurity for forming a source/drain is introduced to the semiconductor thin film (See, e.g., Japanese Patent Application Publication No. JP 2006-49535, hereinafter referred to as Patent Document 1).

Moreover, a method in which laser heat treatment is used as heat treatment for activation of the impurity introduced to the source/drain is proposed. In this case, because of its diffusion coefficient and diffusion time, while the impurity largely diffuses in a liquid-phase portion which is melted by laser, large diffusion hardly occurs in solid-phase diffusion other than the liquid-phase portion. This produces a precipitous band junction between the region melted by laser and the non-melted region (See e.g., “Materials Science Engineering B”, volume 110, March 2004, p 185-189, hereinafter referred as Non-Patent Document 1).

### SUMMARY OF THE INVENTION

However, in the manufacturing of the TFT with the LDD region, misalignment of the resist pattern or mask misalignment with respect to the gate electrode easily causes variation in width of the LDD region on both sides of the channel region. This variation in the LDD region affects TFT characteristics. Therefore, this becomes a factor to cause brightness variation in the driving of the current-drive display element which requires sever current control, for example, such as an organic EL element.

Consequently, it is desirable to provide a manufacturing method of a thin film transistor in which a diffusion layer of shallow junction can be formed in a surface layer of a semiconductor thin film, and thereby, an electric field at a drain terminal may be relaxed without providing an LDD region to uniformly suppress leak current, and further to provide the thin film transistor obtained by the same. The present invention is made in view of the above.

In a manufacturing method of a thin-film semiconductor apparatus according to an embodiment of the present invention, a semiconductor thin film is spot-irradiated with an energy beam in the presence of n-type or p-type impurity, whereby a shallow diffusion layer in which the n-type or p-type impurity is diffused only in a surface layer of the semiconductor thin film.

In the above-described manufacturing method, by extremely limiting the spot irradiation range of the energy beam with respect to the semiconductor thin film to a minute range, the heat generated in this minute range is immediately released, such that only an extremely shallow surface layer in the semiconductor thin film can be instantaneously heated. This can keep the diffusion range of the n-type or p-type impurity in the extremely shallow minute range of the semiconductor thin film.

### BRIEF DESCRIPTION OF THE DRAWINGS

FIG. 1 is a cross-sectional process diagram (No.1) for explaining a manufacturing method of an embodiment.

FIG. 2 is a cross-sectional process diagram (No.2) for explaining the manufacturing method of the embodiment.

FIG. 3 is a diagram for explaining effects of the manufacturing method of the embodiment.

### DETAILED DESCRIPTION OF THE PREFERRED EMBODIMENT

Hereinafter, an embodiment of the present invention is described in detail based on the drawings.

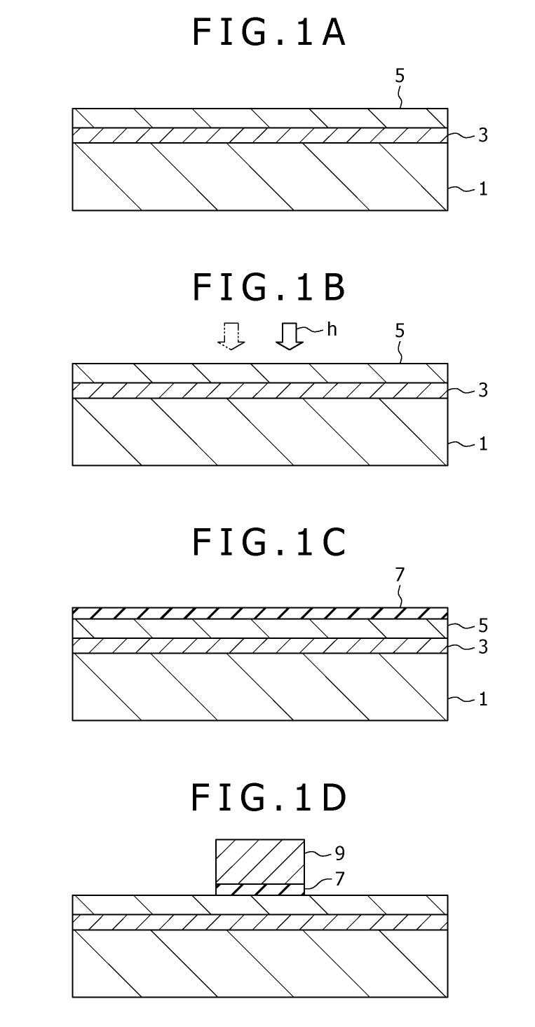

As shown in FIG. 1(1), an oxide silicon (SiO₂) film is first formed as a buffer layer 3 on a surface of a substrate 1 made of glass or plastic. For a film formation method of the buffer layer 3, a publicly-known vacuum film forming technique, such as a chemical vapor deposition (CVD) method, sputter method, and evaporation method, or an insulating layer ordinarily used as an interlayer insulating film or the like of an inorganic type spin on glass (SOG), organic type SOG or the like can be employed.

Subsequently, a semiconductor thin film 5 made of amorphous silicon or microcrystal silicon is formed on the buffer layer 3. For the film forming method of the semiconductor thin film 5, a publicly-known vacuum film forming technique, such as a CVD method, sputter method, and evaporation method, and the like can be used, or a publicly-known application type material such as polysilane type compound can be used to form the film according to a publicly-known anneal process. It is preferable to form the semiconductor thin film 5 with a film thickness of 100 nm or less, and more preferably with a film thickness of 50 nm or less. This is because in the case where a film is crystallized with heat absorbed through the surface layer, using laser as in a low-temperature polysilicon process, it is hard, in terms of energy and time, to completely crystallize the film with a thickness of 100 nm or more. For the same reason, in the case of the film with a thickness of 50 nm or less, a higher quality crystallized film can be formed in a short time with relatively low energy, and additionally the gate control of transistor characteristics becomes easier by making the film thinner.

Thereafter, although the illustration is omitted here, a process for patterning the semiconductor thin film 5 in an island shape per each active region where a thin film transistor is formed is performed as necessary. This patterning is performed, for example, by etching of the semiconductor thin film 5 using a resist pattern as a mask, and after the patterning, the resist pattern is removed.

Next, as shown in FIG. 1(2), the semiconductor thin film 5 is crystallized by irradiating an energy beam h to improve the carrier mobility of the semiconductor thin film 5. Here, as known publicly, according to irradiation conditions such as a type of the used energy beam h (e.g., wavelength of the laser beam), energy density or irradiation time, the silicon film is subjected to the irradiation of the energy beam h in which the extent of crystallization from microcrystal silicon to monocrystal silicon is controlled. It is noted that this crystallization process may be performed as necessary according to the characteristics required for the thin film transistor manufactured here, and the semiconductor thin film 5 may remain in a state of amorphous silicon or microcrystal silicon.

Next, as shown in FIG. 1(3), a gate insulating film 7 is formed on the semiconductor thin film 5. For a film formation method of the gate insulating film 7, a publicly-known vacuum film forming technique, such as a CVD method, sputter method, and evaporation method, or an insulating layer ordinarily used as an interlayer insulating film or the like, such as an inorganic type SOG, organic type SOG or the like can be used. Furthermore, a dielectric film formed by anodic oxidation of a metal film, those formed by a publicly-known method such as a sol-gel method or an Metal Organic Deposition (MOD) method, and the like may be used.

Next, as shown in FIG. 1(4), agate electrode 9 is formed on the gate insulating film 7. At this time, a gate electrode forming film is first formed, and thereafter, patterned to form the gate electrode 9. For a film formation method of the gate electrode forming film, a publicly-known vacuum film forming technique, such as a CVD method, sputter method, and evaporation method, or either of a method of applying and sintering fine metal grains or a plating method may be used. Moreover, the patterning of this gate electrode forming film may be performed by etching with a resist pattern used as a mask. At this time, the gate insulating film 7 at the sides of the gate electrode 9, which is formed by the patterning, is also etched and the gate insulating film 7 is left only in the layer under the gate electrode 9. Moreover, the resist pattern is removed after the patterning.

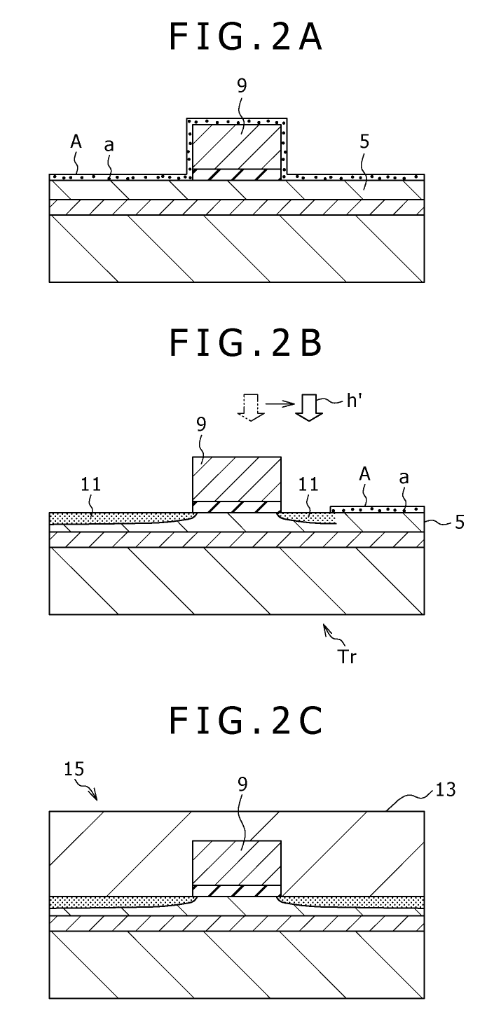

Next, as shown in FIG. 2(1), an impurity film A containing n-type or p-type dopant impurity a is formed on the semiconductor thin film 5.

Here, for example, a solution containing n-type or p-type dopant impurity ions is used. For example, in the case of the n type, a solution containing phosphorus ions of phosphoric acid, pyrophoric acid, and the like, or a solution obtained by dissolving an organic phosphorous compound in an organic solvent such as alcohol is used. On the other hand, in the case of the p type, boric acid aqueous solution is used.

By exposing the semiconductor thin film 5 to atmosphere in which the solution containing the n-type or p-type impurity is volatilized, a liquid film in which the solution is adhered onto the semiconductor thin film 5 is formed and dried to form the impurity film A. At this time, by spraying and dispersing carrier gas containing droplets of the solution from above of the semiconductor thin film 5, the liquid film may be formed on the surface of the semiconductor thin film 5. As the carrier gas, nitrogen gas (N₂) or argon gas (Ar) is used.

It is noted, for the dispersion of the above-described solution, a carburetor is used in which an introduction path of the carrier gas and a release path that releases the carrier gas containing the droplets of the solution are provided in a storage tank of the solution. This storage tank of the carburetor may be provided with an ultrasonic oscillator to facilitate the generation of the droplets of the solution. An ejection port at a tip of the release path of this carburetor is formed into a nozzle shape to eject the solution, and this nozzle-shaped ejection port is configured to move relative to the surface of the semiconductor thin film 5. This allows the solution containing the dopant impurity to be dispersed uniformly onto a surface of the semiconductor thin film 5 formed on the large substrate 1.

In addition to the dispersion of the solution using the carburetor, an application method such as a printing method or a spin coat method may be used to apply the solution and form a liquid film on the surface of the semiconductor thin film 5. The impurity film A may be formed by drying the above formed liquid film.

After the above-described process, as shown in FIG. 2(2), the semiconductor thin film 5 is spot irradiated with an energy beam h′ through the impurity film A containing the n-type or p-type impurity, and thereby, a source/drain 11 in which the impurity a is diffused in the surface layer of the semiconductor thin film 5 is formed.

The above-described spot irradiation of the energy beam h′ is performed while scanning the semiconductor thin film 5 at high speed, and the portions of the semiconductor thin film 5 at the sides of the gate electrode 9 are irradiated with the gate electrode 9 used as a mask.

Also, it is important that by controlling the spot irradiation conditions such as a wavelength, spot diameter, scanning speed, and irradiation energy and the like of the energy beam h′, extents of the impurity a to be diffused on the semiconductor thin film 5 from the impurity film A is adjusted, in a range where the energy beam h′ is irradiated, so that the impurity a is diffused only on the surface layer of the semiconductor thin film 5. Thereby, the thus activated shallow diffusion layer is formed as the source/drain 11.

As the energy beam h′ for performing the above-described spot irradiation, laser beam with a wavelength of, for example, 350 nm˜470 nm is used. This laser beam is used by continuously oscillated it. These lasers with a wavelength of 500 nm or less is suitable for heat treatment of the surface portion, because of a high absorption coefficient in the Si film. Furthermore, in the case of the wavelength area of 350 nm˜470 nm, there is an advantage in that irradiation by a less expensive semiconductor laser is possible.

Here, the above-described spot irradiation conditions of the energy beam h′ are adjusted in such a manner, for example, that the peak top will be within a 10 nm from the film surface in a profile in a depth direction of the dopant impurity concentration in the source/drain 11.

As described above, the source/drain 11 composed of the shallow diffusion layer activated by diffusing the n-type or p-type impurity a is formed only on the surface layer of the semiconductor thin film 5. Thereby, a thin film transistor Tr having no LDD structure is obtained.

After the thin film transistor Tr is formed as described above, an interlayer insulating film 13 is formed in a state covering the gate electrode 9, as shown in FIG. 2(3). For the formation of the interlayer insulating film 13, as in the case of the gate insulating film 7, a publicly-known vacuum film forming technique, such as a CVD method, sputter method, and evaporation method can be used, or those formed by SOG and further a publicly-known technique, such as a sol-gel method and an MOD method, or an organic type insulating film other than SOG may be used.

Thereafter, although the illustration is omitted here, contact holes are formed in the interlayer insulating film 13 first, and subsequently, a source electrode and a drain electrode connected to the source/drain 11 with the contact holes in between are formed. Furthermore, another wiring is layered as necessary to complete the thin-film semiconductor apparatus 15.

According to the above-described manufacturing method of the embodiment, as described by referring to FIG. 2(2), in the process for forming the source/drain 11 in the semiconductor thin film 5, the spot irradiation conditions are controlled, when the spot irradiation of the energy beam h′ is performed from the above of the impurity film A. Thereby, extents of the impurity a to be diffused on the semiconductor thin film 5 from the impurity film A is adjusted, in a range where the energy beam h′ is irradiated, to diffuse the impurity a only on the surface layer of the semiconductor thin film 5. Thus, the activated shallow diffusion layer is formed.

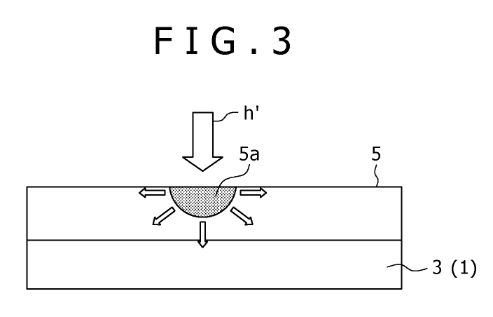

Namely, as shown in FIG. 3, by extremely limiting the spot irradiation range of the energy beam h′ with respect to the semiconductor thin film 5 to a minute range, the heat generated in this minute range is immediately released to the region around the irradiated portion and the substrate 1 under the layer (and the buffer layer 3), as indicated by an arrow in the diagram. This can instantaneously heat only an extremely shallow surface layer 5a in the semiconductor thin film 5, and thus, the activated shallow diffusion layer in which the impurity a is diffused only in this extremely shallow surface layer 5a can be formed.

In contrast, for example, in the case where line beam is irradiated to the semiconductor thin film 5, instead of the energy beam, the heat in the range to which the line beam is irradiated is hardly released peripherally, and the substantial heated portion spreads beyond the irradiated range of the line beam. This makes it difficult to form the diffusion layer only in an extremely shallow range.

As described above, according to the manufacturing method of the embodiment, since the source/drain 11 can be formed as the extremely shallow diffusion layer only in the surface layer of the semiconductor thin film 5, a thin film transistor in which the electric field at the drain terminal is relaxed to suppress leak current without providing an LDD region can be obtained. Further, characteristic variation due to mask misalignment caused in the constitution for relaxing the electric field by the LDD region need not be considered. Thus, the leak current in the thin film transistor Tr can be suppressed uniformly to enable the uniformity of the TFT characteristics. As a result, the current-drive display element such as, for example, an organic EL element can be driven without brightness variation.

Moreover, since the activation of the impurity is performed simultaneously with the diffusion thereof by the spot irradiation of the energy beam h′, the activation by furnace anneal need not be performed. Accordingly, the present embodiment can be applied to the manufacturing of the thin-film semiconductor apparatus in which a low-melting material is used for the substrate 1.

In the above-described embodiment, as described by referring to FIG. 2(2), the configuration is employed in which the semiconductor thin film 5 is spot-irradiated with the energy beam h′ through the impurity film A obtained by drying the liquid film containing the impurity a. However, the spot irradiation of the energy beam h′ to the semiconductor thin film 5 maybe performed in the presence of the dopant impurity. Therefore, the spot irradiation of the energy beam h′ may also be performed to the semiconductor thin film 5 in a state where the semiconductor thin film 5 is exposed to atmosphere in which the solution containing the dopant impurity a is volatilized.

In the above-described embodiment, the case where the source/drain 11 is formed as the shallow diffusion layer formed only in the surface layer of the semiconductor thin film 5 is described. However, the present invention is not limited to the case where the shallow diffusion layer is the source/drain 11, but can be widely applied to configuration where the shallow diffusion layer is formed only in the surface layer of the semiconductor thin film 5. For example, while the gate width of a MOS transistor is very short, and shallow junction of the source/drain portion is required, the present invention can be applied in such a technical area. Moreover, the shallow formation of an n/p layer of a solar battery advantageously improves conversion efficiency, and therefore, the present invention is also applicable in this kind of a case.

According to an embodiment of the present invention described above, since the extremely shallow diffusion layer can be formed on the surface layer of the semiconductor thin film by forming this diffusion layer as the source/drain, the thin film transistor in which an electric field at a drain terminal is relaxed to suppress leak current without providing any LDD region can be attained. Therefore, the characteristic variation deriving from mask alignment caused in the configuration where the electric field is relaxed by the LDD region need not be considered, and the leak current in the thin film transistor can be suppressed uniformly to obtain the uniform TFT characteristics. As a result, a current-drive display element such as, for example, an organic EL element can be driven without brightness variation.

It should be understood by those skilled in the art that various modifications, combinations, sub-combinations and alternations may occur depending on design requirements and other factors insofar as they are within the scope of the appended claims or the equivalents thereof.

What is claimed is:

1. A manufacturing method of a thin-film semiconductor apparatus, wherein
a semiconductor thin film is spot-irradiated with an energy beam in the presence of n-type or p-type impurity to form a shallow diffusion layer in which the impurity is diffused only in a surface layer of the semiconductor thin film.

2. The manufacturing method of a thin-film semiconductor apparatus according to claim 1, wherein
a gate electrode is pattern-formed on the semiconductor thin film with having a gate insulating film in between, and
a source/drain including the shallow diffusion layer is formed by spot-irradiating the semiconductor thin film with the energy beam by using the gate electrode as a mask.

3. The manufacturing method of a thin-film semiconductor apparatus according to claim 1, wherein
the spot irradiation of the energy beam is performed in a state where the impurity is attached to the semiconductor thin film.

4. The manufacturing method of a thin-film semiconductor apparatus according to claim 3, wherein
by exposing the semiconductor thin film to atmosphere in which a solution containing the impurity is volatilized, the solution is adhered onto the semiconductor thin film and dried to form a impurity film, and
the spot irradiation of the energy beam is performed from the above of the impurity film.

5. The manufacturing method of a thin-film semiconductor apparatus according to claim 3, wherein
the impurity film is formed by applying a solution containing the impurity onto the semiconductor thin film to form a film, and drying thereof, and
the spot irradiation of the energy beam is performed from the above of the impurity film.

6. The manufacturing method of a thin-film semiconductor apparatus according to claim 1, wherein
the spot irradiation of the energy beam is performed in a state where the semiconductor thin film is being exposed to atmosphere containing the impurity.

7. The manufacturing method of a thin-film semiconductor apparatus according to claim 1, wherein
a semiconductor thin film with a film thickness of 100 nm or less is formed as the semiconductor thin film.

8. The manufacturing method of a thin-film semiconductor apparatus according to claim 1, wherein
a laser beam with a wavelength of 350 nm to 470 nm is used as the energy beam.

9. The manufacturing method of a thin-film semiconductor apparatus according to claim 1, wherein
the spot irradiation of the energy beam is performed while scanning the surface of the semiconductor thin film.

10. The manufacturing method of a thin-film semiconductor apparatus according to claim 1, wherein
a depth range of the surface layer of the semiconductor thin film whereon the shallow diffusion layer is formed is controlled according to spot irradiation conditions of the energy beam.

11. A thin-film semiconductor apparatus, comprising:
a shallow diffusion layer in which n-type or p-type impurity is diffused only in a surface layer of a semiconductor thin film formed on a substrate.

12. The thin-film semiconductor apparatus according to claim 11, further comprising:
a gate electrode disposed on the semiconductor thin film with a gate insulating film in between;
wherein the shallow diffusion layer is provided in the semiconductor thin film portions at both sides of the gate electrode as a source/drain.
